(19) United States
(12) Patent Application Publication
(10) Pub. No.: US 2026/0004836 A1
(43) Pub. Date: Jan. 1, 2026

(54) STORAGE DEVICE, ELECTRONIC APPARATUS, AND STORAGE DEVICE CONTROL METHOD

(71) Applicant: SONY SEMICONDUCTOR SOLUTIONS CORPORATION, KANAGAWA (JP)

(72) Inventor: TARO TATSUNO, KANAGAWA (JP)

(21) Appl. No.: 18/881,745

(22) PCT Filed: Jul. 11, 2023
(86) PCT No.: PCT/JP2023/025590

§ 371 Date: Jan. 7, 2025

(30) Foreign Application Priority Data
Jul. 28, 2022 (JP) 2022-120138

(51) Int. Cl. G11C 11/16; H10N 50/10

(52) U.S. Cl. CPC G11C 11/1675; G11C 11/1673; H10N 50/10

(57) ABSTRACT

A storage device according to an embodiment of the present disclosure includes a magnetoresistive storage element that changes to at least four identifiable resistance states, and a write unit that changes the magnetoresistive storage element into the at least four identifiable resistance states by changing a magnetization direction of the magnetoresistive storage element or causing a blow current to flow through the magnetoresistive storage element.

### FIELD

The present disclosure relates to a storage device, an electronic apparatus, and a storage device control method.

### BACKGROUND

A magnetoresistive random access memory (MRAM) uses a magnetoresistive element (magnetoresistive storage element) as a storage element, and maintains a state by a magnetization state of a ferromagnetic material, and thus, has a non-volatility in which recorded data is maintained even if a power supply is turned off. A basic structure of the magnetoresistive element is a sandwich structure in which a non-magnetic thin film of an insulator is sandwiched between two magnetic layers made of magnetic thin films. This structure is referred to as a magnetic tunnel junction (MTJ).

In the MRAM, magnetization of one magnetic layer (magnetization fixed layer) of the two magnetic layers is fixed, and magnetization of the other magnetic layer (storage layer) is controlled by an external field. A state where the magnetization of the magnetization fixed layer and the magnetization of the storage layer are parallel to each other is referred to as State 0, and a state where the magnetization of the magnetization fixed layer and the magnetization of the storage layer are antiparallel to each other is referred to as State 1. In this manner, the state (“0” or “1”) is stored in a non-volatile manner by rewriting the parallel or antiparallel state of magnetization.

On the other hand, it is desired to efficiently increase memory capacity of the MRAM in a space-saving manner. In order to increase the memory capacity, for example, proposed is a method in which a state of a tunnel barrier layer (insulating layer) existing between a magnetization fixed layer and a storage layer is changed by using a blow current to add a new resistance state in addition to resistance states in the parallel or antiparallel state, thereby generating three resistance states (see, for example, Patent Literature 1).

### CITATION LIST

### Patent Literature

Patent Literature 1: JP 2020-155727 A

### SUMMARY

### Technical Problem

However, even if the memory capacity increases by the three resistance states, the memory capacity cannot be said to be sufficient due to various factors such as usage conditions, situations, and an increase in desired capacity, and further increase in memory capacity is desired. That is, even under the present circumstances, it is desired to realize an increase in memory capacity in a space-saving manner.

Therefore, the present disclosure provides a storage device, an electronic apparatus, and a storage device control method which enable an increase in memory capacity in a space-saving manner.

### Solution to Problem

A storage device according to an embodiment of the present disclosure includes a magnetoresistive storage element that can be changed to at least four identifiable resistance states; and a write unit that changes the magnetoresistive storage element into the at least four identifiable resistance states by changing a magnetization direction of the magnetoresistive storage element or causing a blow current to flow through the magnetoresistive storage element.

An electronic apparatus according to an embodiment of the present disclosure includes a storage device that stores information, wherein the storage device includes a magnetoresistive storage element that changes to at least four identifiable resistance states, and a write unit that changes the magnetoresistive storage element into the at least four identifiable resistance states by changing a magnetization direction of the magnetoresistive storage element or causing a blow current to flow through the magnetoresistive storage element.

A storage device control method according to an embodiment of the present disclosure includes changing a resistance state of a magnetoresistive storage element to at least four identifiable resistance states by changing a magnetization direction of the magnetoresistive storage element or causing a blow current to flow through the magnetoresistive storage element, the magnetoresistive storage element being variable between the at least four identifiable resistance states.

### BRIEF DESCRIPTION OF DRAWINGS

FIG. 1 is a diagram illustrating a configuration example of a storage device according to an embodiment of the present disclosure.

FIG. 2 is a diagram illustrating a first configuration example of a memory cell according to the embodiment of the present disclosure.

FIG. 3 is a diagram illustrating a second configuration example of the memory cell according to the embodiment of the present disclosure.

FIG. 4 is a diagram illustrating a first configuration example of a magnetoresistive element according to the embodiment of the present disclosure.

FIG. 5 is a diagram illustrating a second configuration example of the magnetoresistive element according to the embodiment of the present disclosure.

FIG. 6 is a diagram illustrating identifiable resistance states of the magnetoresistive element according to the embodiment of the present disclosure.

FIG. 7 is a diagram illustrating multi-value conversion based on the identifiable resistance states of the magnetoresistive element according to the embodiment of the present disclosure.

FIG. 8 is a diagram illustrating four-value conversion based on the identifiable resistance states of the magnetoresistive element according to the embodiment of the present disclosure.

FIG. 9 is a diagram illustrating five-value conversion based on the identifiable resistance states of the magnetoresistive element according to the embodiment of the present disclosure.

FIG. 10 is a diagram illustrating a configuration example of a read circuit and a write circuit according to the embodiment of the present disclosure.

FIG. 11 is a diagram illustrating a first configuration example of the write circuit according to the embodiment of the present disclosure.

FIG. 12 is a diagram illustrating a second configuration example of the write circuit according to the embodiment of the present disclosure.

FIG. 13 is a diagram illustrating a configuration example of an imaging device.

FIG. 14 is a diagram illustrating a configuration example of a distance measurement device.

FIG. 15 is a diagram illustrating an appearance example of a game device.

FIG. 16 is a diagram illustrating a configuration example of the game device.

### DESCRIPTION OF EMBODIMENTS

Hereinafter, embodiments of the present disclosure will be described in detail with reference to the drawings. Note that devices, apparatuses, methods, and the like according to the present disclosure are not limited by the embodiments. Further, the same portions are basically denoted by the same reference signs in the following embodiments, and a repetitive description thereof will be omitted.

One or a plurality of embodiments (including examples and modifications) described below can each be implemented independently. Meanwhile, at least some of the plurality of embodiments to be described hereinafter may be implemented appropriately in combination with at least some of other embodiments. The plurality of embodiments may include novel features different from each other. Therefore, the plurality of embodiments can contribute to achieving mutually different objects or solutions to problems, and can exhibit mutually different effects. Note that the effects of the respective embodiments are merely examples and are not limited, and additional effects may be present.

The present disclosure will be described according to the following item order.
1. Embodiment
1-1. Configuration Example of Storage Device
1-2. Configuration Example of Memory Cell
1-3. Configuration Example of Magnetoresistive Element
1-4. Identifiable Resistance States of Magnetoresistive Element
1-5. Multi-Value Conversion Based on Identifiable Resistance States of Magnetoresistive Element
1-6. Specific Example of Multi-Value Conversion
1-7. Configuration Example and Operation Example of Read Circuit and Write Circuit
1-8. Action and Effect
2. Other Embodiments
3. Configuration Example of Electronic Apparatus
3-1. Imaging Device
3-2. Distance Measurement Device
3-3. Game Device
4. Appendix

### 1. Embodiment

### 1-1. Configuration Example of Storage Device

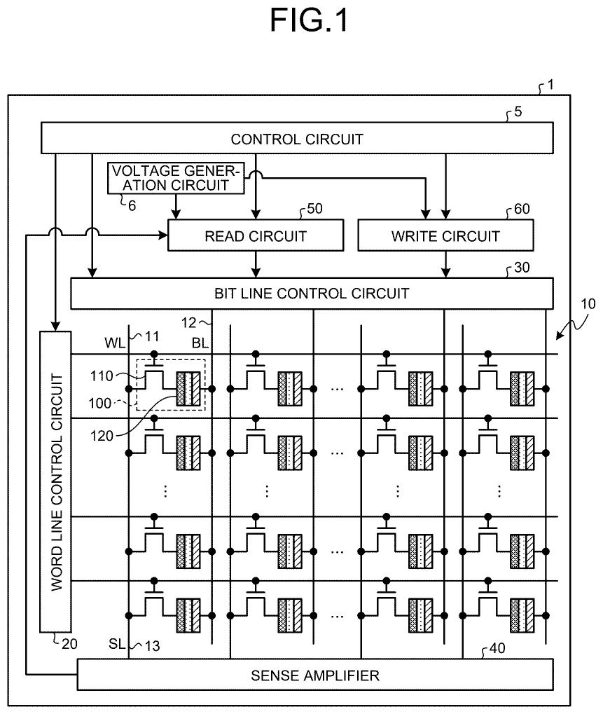

A configuration example of a storage device 1 according to the present embodiment will be described with reference to FIG. 1. FIG. 1 is a diagram illustrating the configuration example of the storage device 1 according to the present embodiment. The storage device 1 is applied to, for example, a large-scale integrated circuit (LSI).

As illustrated in FIG. 1, the storage device 1 according to the present embodiment includes a control circuit 5, a voltage generation circuit 6, a memory cell array 10, a word line control circuit 20, a bit line control circuit 30, a sense amplifier 40, a read circuit 50, and a write circuit 60. Note that the read circuit 50 corresponds to a read unit, the write circuit 60 corresponds to a write unit, and each of the control circuits 5, 20, and 30 corresponds to a controller.

The control circuit 5 performs processing of a write/read command from an external circuit (for example, an arithmetic circuit or the like) and control of data input/output. For example, the control circuit 5 receives a command (a command such as writing or reading) from an external circuit, and controls writing and reading of data based on the received command.

Here, the arithmetic circuit may be, for example, a circuit that performs a logical operation such as an artificial intelligence (AI) function, a recognition function, or machine learning. The arithmetic circuit performs, for example, various kinds of arithmetic processing based on a program. Note that the program, various setting values, and the like may be stored in the storage device 1 for a long period of time, and data and the like generated by arithmetic processing may be stored in the storage device 1 for a short period of time.

The voltage generation circuit 6 generates a voltage to be used for writing and reading data to and from the memory cell array 10, and supplies the generated voltage to the write circuit 60 and the read circuit 50.

The memory cell array 10 is configured by arranging memory cells 100 that store data in a two-dimensional matrix. The memory cell 100 includes a selection element 110 and a magnetoresistive element (magnetoresistive storage element) 120. For example, a voltage controlled (VC)-MRAM cell can be used as the memory cell 100. The selection element 110 is an element that is connected to one end of the magnetoresistive element 120 and controls application of a voltage to the magnetoresistive element 120. As the selection element 110, for example, an n-channel MOS transistor can be used. Furthermore, as the magnetoresistive element 120, for example, a magnetoresistive element such as an MTJ can be used.

Here, in the magnetoresistive element 120, for example, a magnetization direction is variable between a first state and a second state by voltage application. As for an external field used to control the magnetization direction, a current magnetic field generated by causing a current to flow to an external wiring, a method of utilizing a spin transfer torque (STT) effect by causing a current to flow directly to the MTJ, a method of utilizing voltage controlled magnetic anisotropy (VCMA), and the like are used. In addition, a tunnel magneto resistance (TMR) effect is used to read the state of the magnetization direction.

A currently mainstream MRAM is an STT-MRAM that can be reduced in size as compared with a case of using a current magnetic field and can reduce power consumption. On the other hand, attention has been paid to a voltage controlled (VC) MRAM utilizing VCMA, that is, a VC-MRAM because writing can be performed at a high speed and with lower power consumption. The VC-MRAM is non-volatile and has a small area similarly to the STT-MRAM, and the power consumption for writing in the VC-MRAM is smaller than that of the STT-MRAM and is about that of a static random access memory (SRAM). The VC-MRAM is a non-volatile memory having a small area and power consumption.

A word line 11 (WL) and a bit line 12 (BL), which transmit a control signal, are connected to the memory cell 100. In addition, in the memory cell 100, a source line 13 (SL) transmitting a signal from the magnetoresistive element 120 is further disposed. In the memory cell array 10, a plurality of word lines 11 are wired to extend in a row direction, and a plurality of bit lines 12 and source lines 13 are wired to extend in a column direction.

The word line control circuit 20 controls a word line voltage according to a designated address. For example, the word line control circuit 20 selects the word line 11 according to the designated address and outputs a control signal to the selected word line 11.

The bit line control circuit 30 controls a bit line voltage according to a designated address. For example, the bit line control circuit 30 selects the bit line 12 according to the designated address, and outputs the control signal to the selected bit line 12.

The sense amplifier 40 determines a read signal. For example, the sense amplifier 40 reads data by detecting a current flowing through the memory cell 100 at the time of reading. For example, the read data is output to the read circuit 50 and is input to the control circuit 5 via the read circuit 50.

The read circuit 50 controls data read processing. For example, the read circuit 50 is a circuit that performs reading with respect to the memory cell 100 at the intersection of the selected word line 11 and the bit line 12. The read circuit 50 reads the magnetoresistive element 120 via the selection element 110 of the memory cell 100. Reading can be performed by applying a predetermined read voltage to the magnetoresistive element 120 of the memory cell 100 and detecting a current flowing through the memory cell 100. Note that the read voltage is preferably a voltage having a polarity different from that of a write voltage.

The write circuit 60 controls processing of writing data to the memory cell array 10. For example, the write circuit 60 is a circuit that performs writing on the memory cell 100 at the intersection of the selected word line 11 and bit line 12 in the memory cell array 10. The write circuit 60 performs writing on the magnetoresistive element 120 via the selection element 110 of the memory cell 100. Writing can be performed by applying a predetermined write voltage to the magnetoresistive element 120 of the memory cell 100.

### 1-2. Configuration Example of Memory Cell

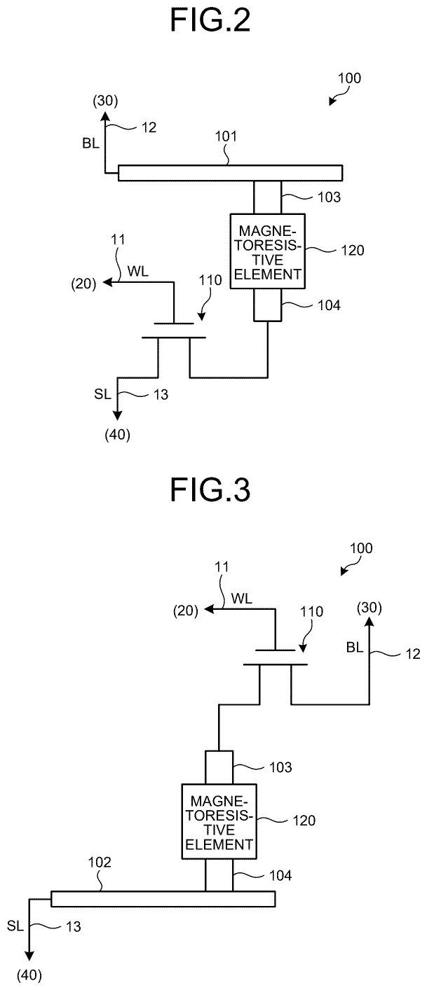

Configuration examples of the memory cell 100 according to the present embodiment will be described with reference to FIGS. 2 and 3. FIGS. 2 and 3 are diagrams each illustrating the configuration example of the memory cell 100 according to the present embodiment. Each drawing is a schematic diagram illustrating the configuration example of the memory cell 100.

In the examples of FIGS. 2 and 3, the selection element 110 and the magnetoresistive element 120 of the memory cell 100 are connected in series, and the selection element 110 includes a drain (drain terminal), a source (source terminal), and a gate (gate terminal). Note that a contact layer 103 or a contact layer 104 corresponds to a connection layer such as a via.

As illustrated in FIG. 2, the magnetoresistive element 120 of the memory cell 100 is connected to a wiring 101 via the contact layer 103, and is connected to the selection element 110 via the contact layer 104. The selection element 110 has the drain connected to the contact layer 104 and the source connected to the source line 13 (SL). Further, the gate of the selection element 110 is connected to the word line 11 (WL). Note that the contact layer 103 is connected to the wiring 101 constituting the bit line 12 (BL). When an on-voltage is applied to the word line 11 (WL), the selection element 110 is energized, and a voltage can be applied to the magnetoresistive element 120.

As illustrated in FIG. 3, the magnetoresistive element 120 of the memory cell 100 is connected to a wiring 102 via the contact layer 104, and is connected to the selection element 110 via the contact layer 103. The selection element 110 has the drain connected to the bit line 12 (BL) and the source connected to the contact layer 103. Further, the gate of the selection element 110 is connected to the word line 11 (WL). Note that the contact layer 104 is connected to the wiring 102 constituting the source line 13 (SL). When an on-voltage is applied to the word line 11 (WL), the selection element 110 is energized, and a voltage can be applied to the magnetoresistive element 120.

As described above, the word line 11 (WL) is connected to the word line control circuit 20 (see FIG. 1). The bit line 12 (BL) is connected to the bit line control circuit 30 (see FIG. 1). The source line 13 (SL) is connected to the sense amplifier 40 (see FIG. 1). A voltage for writing or reading can be applied to the magnetoresistive element 120 by applying a voltage between the bit line 12 (BL) and the source line 13 (SL) and applying the on-voltage for energizing the selection element 110 to the word line 11 (WL).

### 1-3. Configuration Example of Magnetoresistive Element

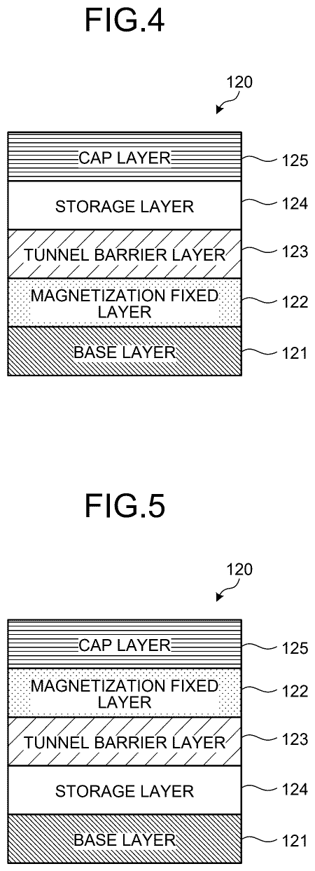

Configuration examples of the magnetoresistive element 120 according to the present embodiment will be described with reference to FIGS. 4 and 5. FIGS. 4 and 5 are diagrams each illustrating the configuration example of the magnetoresistive element 120 according to the present embodiment. Each drawing is a cross-sectional view illustrating the configuration example of the magnetoresistive element 120.

As illustrated in FIGS. 4 and 5, the magnetoresistive element 120 includes a base layer 121, a magnetization fixed layer 122, a tunnel barrier layer (insulating layer) 123, a storage layer (free layer) 124, and a cap layer 125. The magnetoresistive element 120 illustrated in FIG. 4 is configured by sequentially laminating the base layer 121, the magnetization fixed layer 122, the tunnel barrier layer 123, the storage layer 124, and the cap layer 125. On the other hand, the magnetoresistive element 120 illustrated in FIG. 5 is configured by sequentially laminating the base layer 121, the storage layer 124, the tunnel barrier layer 123, the magnetization fixed layer 122, and the cap layer 125.

As the base layer 121, for example, a layer formed of a noble metal such as Cr, Ta, Ru, Au, Ag, Cu, Al, Ti, V, Mo, Zr, Hf, Re, W, Pt, Pd, Ir, or Rh or a transition metal element, and a laminate structure thereof can be used. Further, the base layer 121 can also be made of a conductive nitride such as TiN. For example, the base layer 121 is configured using a film for controlling a crystal orientation of the magnetization fixed layer 122 and improving an adhesion strength to a lower electrode.

The magnetization fixed layer 122 is a layer having magnetic anisotropy and an invariable magnetization direction. The magnetization fixed layer 122 can be made of, for example, CoFeB, a CoFeC alloy, a NiFeB alloy, a NiFeC alloy, or the like. Further, the magnetization fixed layer 122 can have a laminated ferri-pin structure in which a plurality of ferromagnetic layers are laminated with a non-magnetic layer interposed therebetween. As a material of the ferromagnetic layer constituting the magnetization fixed layer 122 having the laminated ferri-pin structure, Co, CoFe, CoFeB, or the like can be used. Further, as a material of the non-magnetic layer, Ru, Re, Ir, Os, or the like can be used.

Further, the magnetization fixed layer 122 can be configured such that the orientation of magnetization is fixed by utilizing antiferromagnetic coupling between an antiferromagnetic layer and a ferromagnetic layer. Examples of a material of the antiferromagnetic layer can include magnetic materials such as a FeMn alloy, a PtMn alloy, a PtCrMn alloy, a NiMn alloy, an IrMn alloy, Nio, and Fe2O3. Further, a non-magnetic element such as Ag, Cu, Au, Al, Si, Bi, Ta, B, C, O, N, Pd, Pt, Zr, Hf, Ir, W, Mo, or Nb can be added to these magnetic materials.

The tunnel barrier layer 123 is arranged adjacent to the storage layer 124 to be described later, and applies an electric field to the storage layer 124 to impart the voltage-controlled magnetic anisotropy effect. The tunnel barrier layer 123 can be made of an oxide of at least one element selected from the group of Mg, Al, Ti, Si, Zn, Zr, Hf, Ta, Bi, Cr, Ga, La, Gd, Sr, and Ba, or a nitride of at least one element selected from the group of Mg, Al, Ti, Si, Zn, Zr, Hf, Ta, Bi, Cr, Ga, La, Gd, Sr, and Ba. Further, it can also be configured using an insulator such as MgF2, CaF, SrTiO2, AlLaO3, or AlNO, a dielectric, and a semiconductor. It is also possible to have a structure in which these layers are laminated. Note that a thickness of the tunnel barrier layer 123 is preferably equal to or more than 0.6 nm.

The storage layer 124 is a layer having magnetic anisotropy and a variable magnetization direction. Further, the storage layer 124 is a layer having the VCMA effect. A state where the magnetization direction of the storage layer 124 and the magnetization direction of the magnetization fixed layer 122 are identical and a state where the magnetization direction of the storage layer 124 and the magnetization direction of the magnetization fixed layer 122 are different are referred to as a parallel state and an antiparallel state, respectively. The magnetoresistive element 120 is in a low resistance state in the parallel state, and is in a high resistance state in the antiparallel state. The magnetization direction of the storage layer 124 can be changed by applying a voltage to the magnetoresistive element 120 as described above.

Further, the storage layer 124 can be made of cobalt iron (CoFe), cobalt iron boron (CoFeB), Fe, iron boride (FeB), or the like. Further, it is also possible to adopt a configuration including a transition metal (Hf, Ta, W, Re, Ir, Pt, Au, Zr, Nb, Mo, Ru, Rh, Pd, Ag, Ti, V, Cr, Mn, Ni, or Cu) or the like. In addition, a nitride or an oxide may be included. Further, iridium (Ir) or osmium (Os) can be used as a material that induces a proximity magnetic moment to the magnetic material. Note that a heavy metal can also be added to the storage layer 124 to improve the voltage-controlled magnetic anisotropy effect. A thickness of the storage layer 124 is preferably equal to or less than 3.0 nm.

Further, the storage layer 124 may have a laminate structure in which a plurality of ferromagnetic layers are laminated with a non-magnetic layer interposed therebetween. At this time, two ferromagnetic layers adjacent to each other with the non-magnetic layer interposed therebetween may be exchange-coupled. The non-magnetic layer can be made of Mg, Al, Ti, Si, Zn, Zr, Hf, Ta, Bi, Cr, Ga, La, Gd, Sr, Ba, W, Re, Ir, Pt, Au, Nb, Mo, Ru, Rh, Pd, Ag, V, Mn, Ni, Cu, or the like.

The cap layer 125 is a layer that prevents diffusion of a metal from a wiring member connected to the magnetoresistive element 120. The cap layer 125 can be made of a metal such as Cr, Ta, Ru, Au, Ag, Cu, Al, Ti, V, Mo, Zr, Hf, Re, W, Pt, Pd, Ir, or Rh. Further, the cap layer 125 can be configured using a layer formed of an alloy containing them or a transition metal element. Further, the cap layer 125 can also be configured by laminating them. Further, the cap layer 125 can also be made of a conductive nitride such as TiN.

The above-described various layers can be produced by, for example, a physical vapor deposition (PVD) method typified by a sputtering method, an ion beam deposition method, and a vacuum vapor deposition method, and a chemical vapor deposition (CVD) method typified by an atomic layer deposition (ALD) method. Further, patterning of these layers can be performed by a reactive ion etching (RIE) method or an ion milling method. It is preferable to form the various layers consecutively in a vacuum apparatus, and it is preferable to perform patterning thereafter.

### 1-4. Identifiable Resistance States of Magnetoresistive Element

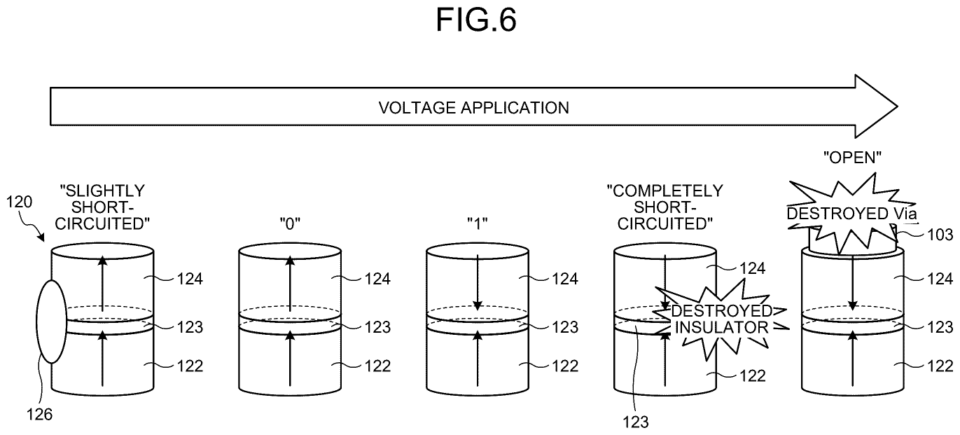

Identifiable resistance states of the magnetoresistive element 120 according to the present embodiment will be described with reference to FIG. 6. FIG. 6 is a diagram illustrating the identifiable resistance states of the magnetoresistive element 120 according to the present embodiment.

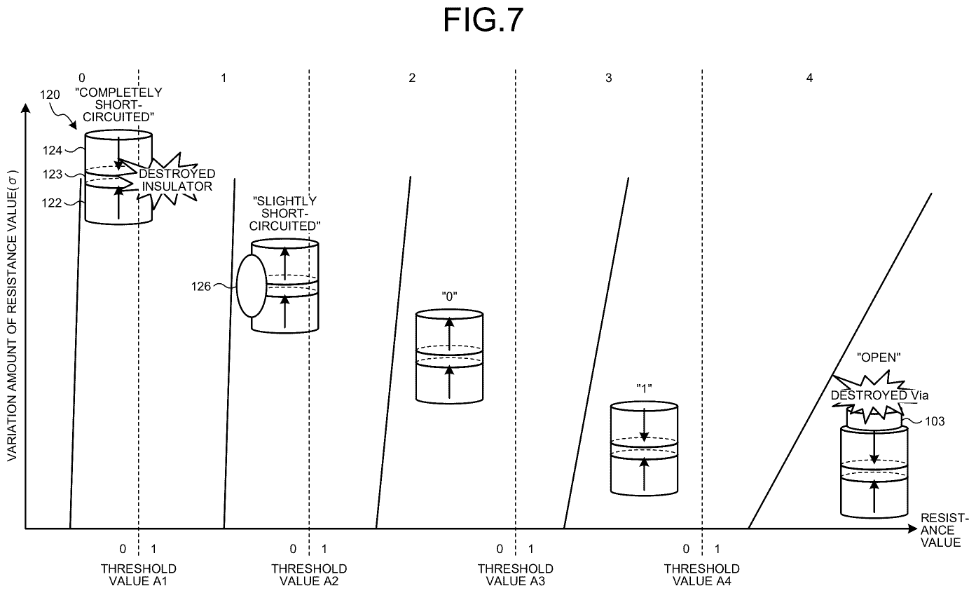

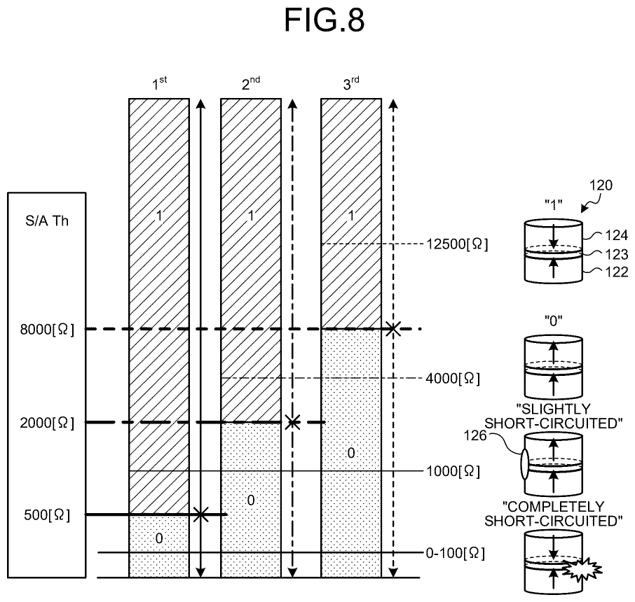

As illustrated in FIG. 6, the magnetoresistive element 120 according to the present embodiment has five identifiable resistance states. In the example of FIG. 6, layers other than the main magnetization fixed layer 122, the tunnel barrier layer 123, and the storage layer 124 in the magnetoresistive element 120 are appropriately omitted. The same applies to subsequent FIGS. 7 and 8.

The five resistance states are defined as the resistance states of “slightly short-circuited”, “0”, “1”, “completely short-circuited”, and “open”. The voltage application for changing the five resistance states is supplied to the magnetoresistive element 120 by the write circuit 60. The voltage application increases from the left to the right of the arrow in FIG. 6. A relationship between the individual resistance values of “slightly short-circuited”, “0”, “1”, “completely short-circuited”, and “open” will be described later in detail.

The magnetoresistive element 120 in an initial resistance state (for example, the resistance state of “slightly short-circuited”) enters a resistance state of “0” when a first voltage is applied and enters a resistance state of “1” when a second voltage (>first voltage) is applied. Furthermore, the magnetoresistive element 120 enters a resistance state of “completely short-circuited” when a third voltage (>the second voltage) is applied, and enters a resistance state of “open” when a fourth voltage (>the third voltage) is applied.

Here, the initial resistance state is, for example, a resistance state of “slightly short-circuited”, but the present invention is not limited thereto. The resistance state of “slightly short-circuited” is a state in which the magnetization fixed layer 122 and the storage layer 124 are conducted by a conductive layer 126. The conductive layer 126 is, for example, a degenerated layer. The degenerated layer is, for example, a layer formed by degeneration of one or both of the magnetization fixed layer 122 and the storage layer 124. Such a conductive layer 126 is provided on the outer peripheral surface of the magnetoresistive element 120 to cross the tunnel barrier layer 123. The conductive layer 126 is formed by, for example, narrowing a space of the memory cell 100, skipping trimming performed to remove attached substances to be the conductive layer 126 (for example, a re-adhering substance or the like), or intentionally dripping a metal.

Note that the conductive layer 126 is formed on the outer peripheral surface of the magnetoresistive element 120, but is not limited thereto, and for example, may be formed in the tunnel barrier layer 123. However, to facilitate the formation of the conductive layer 126, it is desirable to form the conductive layer 126 on the outer peripheral surface of the magnetoresistive element 120.

When the first voltage, the second voltage, the third voltage, or the fourth voltage described above is applied to the magnetoresistive element 120, a blow current flows through the magnetoresistive element 120, the conductive layer 126 is destroyed to be in a non-conductive state, and the resistance state of the magnetoresistive element 120 changes according to the first voltage, the second voltage, the third voltage, or the fourth voltage applied to the magnetoresistive element 120.

For example, when the first voltage is applied to the magnetoresistive element 120, the magnetization direction of the magnetization fixed layer 122 and the magnetization direction of the storage layer 124 become parallel (the same direction) to each other. As a result, the magnetoresistive element 120 changes from the initial resistance state to the resistance state of “0”. The resistance state of “0” is a state in which the magnetization direction of the magnetization fixed layer 122 and the magnetization direction of the storage layer 124 are parallel to each other.

In addition, when the second voltage is applied to the magnetoresistive element 120, the magnetization direction of the magnetization fixed layer 122 and the magnetization direction of the storage layer 124 become antiparallel (opposite) to each other. As a result, the magnetoresistive element 120 changes from the initial resistance state to the resistance state of “1”. The resistance state of “1” is a state in which the magnetization direction of the magnetization fixed layer 122 and the magnetization direction of the storage layer 124 are antiparallel to each other. Note that the magnetoresistive element 120 can return from the resistance state of “1” to the resistance state of “0” by the application of the first voltage.

In addition, when the third voltage is applied to the magnetoresistive element 120, a blow current flows through the tunnel barrier layer 123, and the tunnel barrier layer 123 is destroyed to be in an energized state (completely short-circuited). As a result, the magnetoresistive element 120 changes from the initial resistance state to the resistance state of “completely short-circuited”. The resistance state of “completely short-circuited” is a state in which the tunnel barrier layer 123 is destroyed to be in an energized state.

In addition, when the fourth voltage is applied to the magnetoresistive element 120, a blow current flows through the contact layer 103, and the contact layer 103 is destroyed to be in a non-energized state (open). As a result, the magnetoresistive element 120 changes from the initial resistance state to the resistance state of “open”. The resistance state of “open” is a state in which the contact layer 103 is destroyed to be in a non-energized state.

As described above, the resistance state of the magnetoresistive element 120 can be changed to five resistance states by voltage application. For example, the magnetoresistive element 120 can be changed from the resistance state of “slightly short-circuited” to any resistance state of “0”, “1”, “completely short-circuited”, and “open”, can be changed from the resistance state of “0” to any resistance state of “1”, “completely short-circuited”, and “open”, can be changed from the resistance state of “1” to any resistance state of “0”, “completely short-circuited”, and “open”, and can be changed from the resistance state of “completely short-circuited” to the resistance state of “open”.

The magnetoresistive element 120 is an element capable of rewriting information. By changing the voltage application (current supply), the resistance state of the magnetoresistive element 120 can be changed to any one of the five resistance states. For example, it is possible to change the resistance state of the magnetoresistive element 120, that has become the resistance state of “1” by voltage application, to the resistance state of “completely short-circuited” by performing voltage application again to the magnetoresistive element 120. This is merely an example, and it is possible to rewrite information by changing the magnetoresistive element 120 from a certain resistance state to another resistance state as described above.

By determining which one of the five resistance states the magnetoresistive element 120 is in, multi-value conversion can be achieved. That is, according to the present embodiment, information can be recorded in multiple values, and further, information can be rewritten. To determine which one of the five resistance states the magnetoresistive element 120 is in, means for setting a threshold value to realize multi-value conversion will be described in detail below.

### 1-5. Multi-Value Conversion Based on Identifiable Resistance States of Magnetoresistive Element

Multi-value conversion based on the identifiable resistance states of the magnetoresistive element 120 according to the present embodiment will be described with reference to FIG. 7. FIG. 7 is a diagram illustrating multi-value conversion based on the identifiable resistance states of the magnetoresistive element 120 according to the present embodiment.

As illustrated in FIG. 7, in the present embodiment, multi-value conversion of 0, 1, 2, 3, and 4 (five-value bits) is realized according to five identifiable resistance states of the magnetoresistive element 120. A maximum of five value bits are realized, but the present invention is not limited thereto, and for example, four value bits of 0, 1, 2, and 3 may be realized.

In the example of FIG. 7, a graph showing a relationship between a resistance value and a variation amount (σ) of the resistance value for each resistance state of the magnetoresistive element 120 is illustrated. As illustrated in FIG. 7, the resistance value of the magnetoresistive element 120 increases in the order of the resistance states of “completely short-circuited”, “slightly short-circuited”, “0”, “1”, and “open”. The resistance state of “slightly short-circuited” is a state in which the resistance value is higher than that of the resistance state of “completely short-circuited”.

For example, the pieces of information 0 to 4 are associated with the five resistance states of the magnetoresistive element 120. Specifically, the resistance state of “completely short-circuited” is associated with 0, the resistance state of “slightly short-circuited” is associated with 1, the resistance state of “0” is associated with 2, the resistance state of “1” is associated with 3, and the resistance state of “open” is associated with 4. Then, four threshold values A1, A2, A3, and A4 are set by the read circuit 50 for the five resistance states. Information is read by the read circuit 50 according to the threshold values A1, A2, A3, and A4.

For example, the information is 0 when the resistance value of the magnetoresistive element 120 is equal to or less than the threshold value A1, the information is 1 when the resistance value of the magnetoresistive element 120 is equal to or less than the threshold value A2 higher than the threshold value A1, and the information is 2 when the resistance value of the magnetoresistive element 120 is equal to or less than the threshold value A3 higher than the threshold value A2. The information is 3 when the resistance value of the magnetoresistive element 120 is equal to or less than the threshold value A4 higher than the threshold value A3, and the information is 4 when the resistance value of the magnetoresistive element 120 is higher than the threshold value A4.

By using the five resistance states and the four threshold values A1, A2, A3, and A4 as such, multi-value conversion can be realized. For example, four-value conversion or five-value conversion can be realized as the multi-value conversion, but it is preferable to realize at least equal to or more than four-value conversion from the viewpoint of increasing storage capacity, and a specific example of realizing the multi-value conversion will be described in detail below.

### 1-6. Specific Example of Multi-Value Conversion

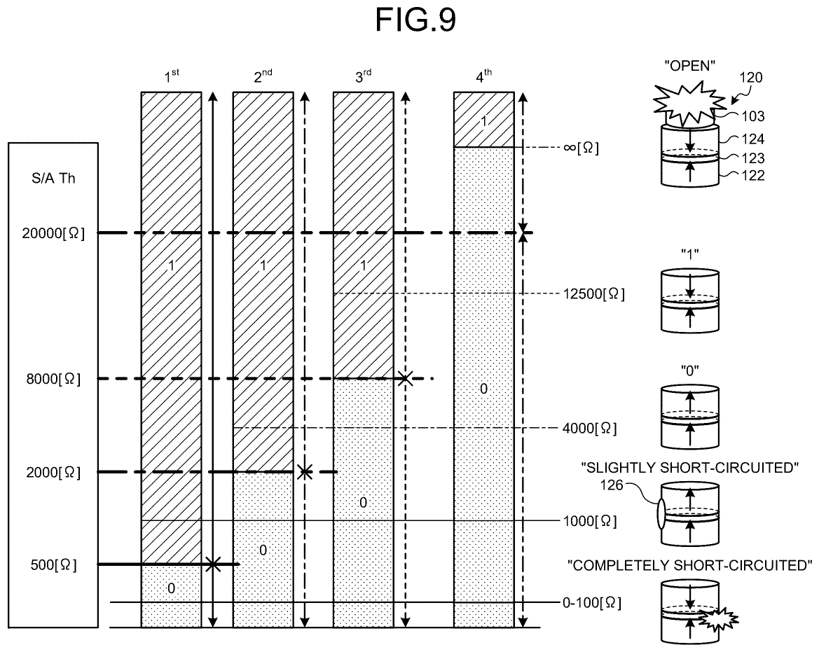

Specific examples of multi-value conversion based on the identifiable resistance states of the magnetoresistive element 120 according to the present embodiment will be described with reference to FIGS. 8 and 9.

### (Four-Value Conversion)

FIG. 8 is a diagram illustrating four-value conversion based on the identifiable resistance states of the magnetoresistive element 120 according to the embodiment of the present disclosure.

In the example of FIG. 8, the resistance value of the magnetoresistive element 120 is about 0 to 100 (Ω) in the resistance state of “completely short-circuited”, about 1, 000 (Ω) in the resistance state of “slightly short-circuited”, about 4, 000 (Ω) in the resistance state of “0”, and about 12,500 (Ω) in the resistance state of “1”. In response thereto, a threshold value Th is set to, for example, 500 (Ω), 2,000 (Ω), or 8,000 (Ω).

As illustrated in FIG. 8, the read circuit 50 reads the resistance value of the magnetoresistive element 120 with the threshold value Th set to 500 (Ω), and inputs a comparison result between the resistance value and the threshold value Th into a first register (1st). For example, the read circuit 50 compares the read resistance value with 500 (Ω), sets a determination result to 0 when it is determined that the read resistance value is equal to or less than 500 (Ω), sets the determination result to 1 when it is determined that the read resistance value is higher than 500 (Ω), and inputs the determination result of 0 or 1 into the first register (1st).

Next, the read circuit 50 sets the threshold value Th to 2,000 (Ω), reads the resistance value of the magnetoresistive element 120, and inputs a comparison result between the resistance value and the threshold value Th into a second register (2nd). For example, the read circuit 50 compares the read resistance value with 2,000 (Ω), sets the determination result to 0 when it is determined that the read resistance value is equal to or less than 2,000 (Ω), sets the determination result to 1 when it is determined that the read resistance value is higher than 2,000 (Ω), and inputs the determination result of 0 or 1 into the second register (2nd).

Next, the read circuit 50 sets the threshold value Th to 8,000 (Ω), reads the resistance value of the magnetoresistive element 120, and inputs a comparison result between the resistance value and the threshold value Th into a third register (3rd). For example, the read circuit 50 compares the read resistance value with 8,000 (Ω), sets the determination result to 0 when it is determined that the read resistance value is equal to or less than 8, 000 (Ω), sets the determination result to 1 when it is determined that the read resistance value is higher than 8,000 (Ω), and inputs the determination result of 0 or 1 into the third register (3rd).

Thereafter, the read circuit 50 realizes four-value conversion (0, 1, 2, 3) based on each comparison result, that is, each determination result input into the first register to the third register. For example, when each of the determination results of the first register, the second register, and the third register is 0, the information becomes 0, and when the determination result of the first register is 1 and each of the determination results of the second register and the third register is 0, the information becomes 1. Further, when each of the determination results of the first register and the second register is 1 and the determination result of the third register is 0, the information becomes 2, and when each of the determination results of the first register, the second register, and the third register is 1, the information becomes 3.

### (Five-Value Conversion)

FIG. 9 is a diagram illustrating five-value conversion based on the identifiable resistance states of the magnetoresistive element 120 according to the present embodiment.

In the example of FIG. 9, similarly to the example of FIG. 8, the resistance value of the magnetoresistive element 120 is about 0 to 100 (Ω) in the resistance state of “completely short-circuited”, about 1,000 (Ω) in the resistance state of “slightly short-circuited”, about 4,000 (Ω) in the resistance state of “0”, about 12, 500 (Ω) in the resistance state of “1”, and in addition to the example of FIGS. 8, ∞ (Ω) in the resistance state of “open”,. Therefore, the threshold value Th is set to, for example, 500 (Ω), 2,000 (Ω), 8,000 (Ω), and 20,000 (Ω).

As illustrated in FIG. 9, similarly to the example of FIG. 8, the read circuit 50 reads the resistance value of the magnetoresistive element 120 with the threshold value Th set to 500 (Ω), inputs a comparison result (determination result) between the resistance value and the threshold value Th into the first register (1st), reads the resistance value of the magnetoresistive element 120 with the threshold value Th set to 2,000 (Ω), and inputs a comparison result (determination result) between the resistance value and the threshold value Th into the second register (2nd). Next, the read circuit 50 reads the resistance value of the magnetoresistive element 120 with the threshold value Th set to 8,000 (Ω), inputs a comparison result (determination result) between the resistance value and the threshold value Th into the third register (3rd), reads the resistance value of the magnetoresistive element 120 with the threshold value Th set to 20,000 (Ω), and inputs a comparison result (determination result) between the resistance value and the threshold value Th into a fourth register (4th).

Thereafter, the read circuit 50 realizes five-value conversion (0, 1, 2, 3, 4) based on each comparison result, that is, each determination result input into the first register to the fourth register. For example, when each of the determination results of the first register, the second register, the third register, and the fourth register is 0, the information becomes 0, and when the determination result of the first register is 1 and each of the determination results of the second register, the third register, and the fourth register is 0, the information becomes 1. Further, when each of the determination results of the first register and the second register is 1 and each of the determination results of the third register and the fourth register is 0, the information becomes 2, and when each of the determination results of the first register, the second register, and the third register is 1 and the determination result of the fourth register is 0, the information becomes 3. When each of the determination results of the first register, the second register, the third register, and the fourth register is 1, the information becomes 4.

As such, four-value conversion and five-value conversion can be realized. A specific configuration example and an operation example of the read circuit 50 that realizes four-value conversion will be described in detail below. Note that a configuration example and an operation example of the read circuit 50 and the write circuit 60 that realize the four-value conversion to be described below are merely examples, and it is possible to configure the read circuit 50 and the write circuit 60 that realize the five-value conversion by appropriately adding circuits to the read circuit 50 and the write circuit 60 that realize the four-value conversion.

### 1-7. Configuration Example and Operation Example of Read Circuit and Write Circuit

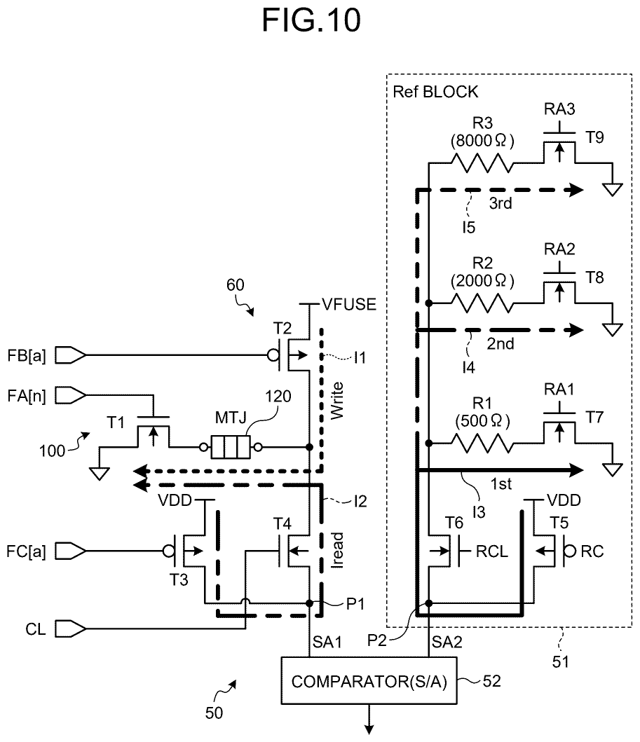

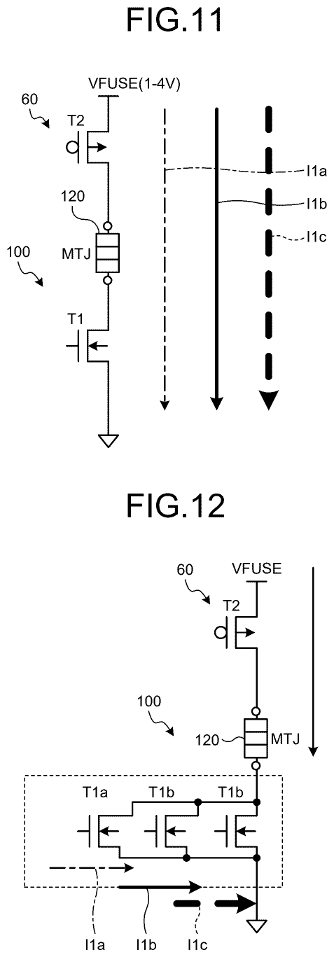

The configuration examples and the operation examples of the read circuit 50 and the write circuit 60 according to the present embodiment will be described with reference to FIGS. 10 to 12. FIG. 10 is a diagram illustrating the configuration example of the read circuit 50 and the write circuit 60 according to the present embodiment. FIGS. 11 and 12 are diagrams each illustrating the configuration example of the write circuit 60 according to the present embodiment.

### (Configuration Example of Read Circuit)

As illustrated in FIG. 10, the read circuit 50 includes a charge transistor T3, a bit line selection transistor T4, a reference voltage generator 51, and a comparator 52. For example, the units are arranged for each column. The read circuit 50 is a circuit that reads (determines) information recorded in the magnetoresistive element 120 in multiple values from the memory cell 100 to be read. Note that the reference voltage generator 51 corresponds to a generation unit, and the comparator 52 corresponds to a determination unit.

The charge transistor T3 is a transistor that is turned on in response to a control signal FC(a) applied to a gate terminal thereof. In the example of FIG. 10, the charge transistor T3 includes a PMOS field effect transistor (FET). A source terminal of the charge transistor T3 is connected to a potential line of a power supply voltage VDD, a drain terminal of the charge transistor T3 is connected to an input terminal of the comparator 52, and the gate terminal of the charge transistor T3 is connected to an output terminal of the word line control circuit 20 (or the control circuit 5). Note that the bit line selection transistor T4 is turned on when a control signal FA(n) of a low level is input to the gate terminal thereof, and is turned off when the control signal FA(n) of a high level is input to the gate terminal thereof.

The bit line selection transistor T4 is a transistor that is turned on in response to a control signal CL applied to a gate terminal thereof. The bit line selection transistor T4 is connected to the magnetoresistive element 120. In the example of FIG. 10, the bit line selection transistor T4 is configured by an NMOS FET. The source terminal of the bit line selection transistor T4 is connected to one end of the magnetoresistive element 120, the drain terminal of the bit line selection transistor T4 is connected to the input terminal of the comparator 52, and the gate terminal of the bit line selection transistor T4 is connected to the output terminal of the word line control circuit 20 (or the control circuit 5). Note that the bit line selection transistor T4 is turned on when the control signal FA(n) of the high level is input to the gate terminal thereof, and is turned off when the control signal FA(n) of the low level is input to the gate terminal thereof.

The reference voltage generator 51 includes a plurality of reference transistors T5 to T9 and a plurality of reference resistance elements R1 to R3. The reference voltage generator 51 is a circuit that generates a reference voltage (reference voltage signal) serving as a reference (threshold value) when reading information recorded in multiple values in the magnetoresistive element 120.

The first reference transistor T5 is a transistor that is turned on according to a control signal RC applied to a gate terminal thereof. In the example of FIG. 10, the first reference transistor T5 is configured by a PMOS FET. A source terminal of the first reference transistor T5 is connected to the potential line of the power supply voltage VDD, a drain terminal of the first reference transistor T5 is connected to the input terminal of the comparator 52, and the gate terminal of the first reference transistor T5 is connected to the output terminal of the control circuit 5. Note that the first reference transistor T5 is turned on when the control signal RC of the low level is input to the gate terminal thereof, and is turned off when the control signal RC of the high level is input to the gate terminal thereof.

The second reference transistor T6 is a transistor that is turned on according to a control signal RCL applied to a gate terminal thereof. In the example of FIG. 10, the second reference transistor T6 is configured by an NMOS FET. A source terminal of the second reference transistor T6 is connected to one end of each of the reference resistance elements R1 to R3, a drain terminal of the second reference transistor T6 is connected to the input terminal of the comparator 52, and the gate terminal of the second reference transistor T6 is connected to the output terminal of the control circuit 5. Note that the second reference transistor T6 is turned on when the control signal RCL of the high level is input to the gate terminal thereof, and is turned off when the control signal RCL of the low level is input to the gate terminal thereof.

Each of the third to fifth reference transistors T7 to T9 is a transistor that is turned on in response to a control signal RA (RA1, RA2, RA3) applied to a corresponding one of gate terminals thereof. In the example of FIG. 10, each of the third to fifth reference transistors T7 to T9 is constituted by an NMOS FET. Respective source terminals of the third to fifth reference transistors T7 to T9 are connected to a ground potential (GND), respective drain terminals of the third to fifth reference transistors T7 to T9 are respectively connected to one ends of the reference resistance elements R1 to R3, and respective gate terminals of the third to fifth reference transistors T7 to T9 are respectively connected to the output terminals of the control circuit 5. Note that each of the third to fifth reference transistors T7 to T9 is turned on when the control signal RA (RA1, RA2, RA3) of the high level is input to the gate terminals thereof, and is turned off when the control signal RA of the low level is input to the gate terminals thereof.

Each of the reference resistance elements R1 to R3 is a resistance element that defines a resistance value. The reference resistance element R1 is a resistance element having 500 (Q). The reference resistance element R2 is a resistance element having 2,000 (2). The reference resistance element R3 is a resistance element having 8,000 (2). One end of each of the reference resistance elements R1 to R3 is connected to the source terminal of the second reference transistor T6, and the other end of each of the reference resistance elements R1 to R3 is connected to the drain terminal of each of the third to fifth reference transistors T7 to T9.

The reference voltage generator 51 having such a configuration generates a reference voltage Vref according to each of the resistance values of the reference resistance elements R1 to R3, for example, 500 (Ω), 2,000 (Ω), and 8,000 (Ω). The reference voltage Vref functions as a threshold value.

To generate a first reference current 13, the reference voltage generator 51 supplies the control signal RC of the low level, the control signal RCL of the high level, and the control signal RA1 of the high level to the respective gates of the first to third reference transistors T5 to T7. As a result, the first to third reference transistors T5 to T7 are turned on, the reference resistance element R1 is biased, and the first reference current 13 is generated. Here, the first reference current 13 flows toward the ground potential from the power supply voltage VDD via the reference resistance element R1. To generate a second reference current 14, the

reference voltage generator 51 supplies the control signal RC of the low level, the control signal RCL of the high level, and the control signal RA2 of the high level to the respective gates of the first, second, and fourth reference transistors T5, T6, and T8. As a result, the first, second, and fourth reference transistors T5, T6, and T8 are turned on, the reference resistance element R2 is biased, and the second reference current 14 is generated. Here, the second reference current 14 flows toward the ground potential from the power supply voltage VDD via the reference resistance element R2.

To generate a third reference current 15, the reference voltage generator 51 supplies the control signal RC of the low level, the control signal RCL of the high level, and the control signal RA3 of the high level to the respective gates of the first, second, and fifth reference transistors T5, T6, and T9. As a result, the first, second, and fifth reference transistors T5, T6, and T9 are turned on, the reference resistance element R3 is biased, and the third reference current 15 is generated. Here, the third reference current 15 flows toward the ground potential from the power supply voltage VDD via the reference resistance element R3.

The comparator 52 includes, for example, a sense amplifier. Here, the comparator 52 corresponds to the sense amplifier 40 (see FIG. 1) and the read circuit 50 includes the sense amplifier 40, but the present invention is not limited thereto, and the read circuit 50 and the sense amplifier 40 may be provided separately. Here, the read circuit 50 and the sense amplifier 40 correspond to a read unit.

In addition, the comparator 52 includes a pair of input terminals. One input terminal of the comparator 52 is connected to a connection point P1 (hereinafter, referred to as a first connection point P1) between the drain terminal of the charge transistor T3 and the drain terminal of the bit line selection transistor T4 in the read circuit 50. The other input terminal of the comparator 52 is connected to a connection point P2 (hereinafter, referred to as a second connection point P2) between the drain terminal of the first reference transistor T5 and the drain terminal of the second reference transistor T6 in the reference voltage generator 51. The comparator 52 compares a voltage Vm (voltage related to the resistance value of the magnetoresistive element 120) at the first connection point P1 input to one input terminal thereof with the reference voltage (the threshold value voltage) Vref at the second connection point P2 input to the other input terminal thereof, and outputs the comparison result.

### (Configuration Example of Write Circuit)

As illustrated in FIG. 10, the write circuit 60 includes a fuse transistor T2. In the example of FIG. 10, the memory cell 100 includes a selection transistor T1 and the magnetoresistive element 120. The selection transistor T1 is an example of the selection element 110, and can function as a part of the write circuit 60.

The selection transistor T1 is a transistor that is turned on in response to the control signal FA(n) applied to a gate terminal thereof. The selection transistor T1 is connected to the magnetoresistive element 120. In the example of FIG. 10, the selection transistor T1 is configured by an NMOS FET. A source terminal of the selection transistor T1 is connected to the ground potential (GND), a drain terminal of the selection transistor T1 is connected to one end of the magnetoresistive element 120, and the gate terminal of the selection transistor T1 is connected to the output terminal of the word line control circuit 20 (or the control circuit 5). Note that the selection transistor T1 is turned on when the control signal FA(n) of the high level is input to the gate terminal thereof, and is turned off when the control signal FA(n) of the low level is input to the gate terminal thereof.

The fuse transistor T2 is a transistor that is turned on in response to a control signal FB(a) applied to a gate terminal thereof. The fuse transistor T2 is connected to the magnetoresistive element 120. In the example of FIG. 10, the fuse transistor T2 is configured by a PMOS FET. A source terminal of the fuse transistor T2 is connected to a power supply voltage VFUSE, a drain terminal of the fuse transistor T2 is connected to one end of the magnetoresistive element 120, and the gate terminal of the fuse transistor T2 is connected to the output terminal of the bit line control circuit 30 (or the control circuit 5). Note that the fuse transistor T2 is turned on when the control signal FB(a) of the low level is input to the gate terminal thereof, and is turned off when the control signal FB(a) of the high level is input to the gate terminal thereof.

The power supply voltage VFUSE can be changed within a range of 1 to 4 V, for example, as illustrated in FIG. 11. The power supply voltage VFUSE is changed by the control circuit 5 according to information to be written (for example, 0, 1, 2,3), and supplies a plurality of currents I1a, I1b, and I1c having different magnitudes to the magnetoresistive element 120. For example, a first voltage that brings the magnetoresistive element 120 from a certain resistance state (for example, the resistance state of “slightly short-circuited”) to a state of “0” state, a second voltage (>the first voltage) that brings the magnetoresistive element 120 from a certain resistance state to a resistance state of “1”, and a third voltage (>the second voltage) that brings the magnetoresistive element 120 from a certain resistance state to a state of “completely short-circuited” are generated as the power supply voltage VFUSE. For example, the power supply voltage VFUSE may be generated by the voltage generation circuit 6.

Note that a plurality of voltages (currents) having different magnitudes can be supplied to the magnetoresistive element 120 by means other than changing the voltage value of the power supply voltage VFUSE to supply a plurality of voltages (currents) having different magnitudes to the magnetoresistive element 120. For example, a plurality of voltages having different magnitudes may be supplied to the magnetoresistive element 120 by setting the power supply voltage VFUSE to be constant and raising and lowering the power supply voltage VFUSE by a raising/lowering circuit.

For example, as illustrated in FIG. 12, three selection transistors T1a, T1b, and T1c may be provided in parallel (in the case of four-value conversion). The select transistors T1a, T1b, and T1c function as a part of the write circuit 60. To generate voltages (currents) having different magnitudes, the write circuit 60 performs a first operation of turning on only the selection transistor T1a, a second operation of turning on only two selection transistors T1a and T1b, and a third operation of turning on three selection transistors T1a, T1b, and T1c. The voltage (current) supplied to the magnetoresistive element 120 changes according to the number of selection transistors T1a, T1b, and T1c turned on. As a result, a plurality of currents I1a, I1b, and I1c having different magnitudes are supplied to the magnetoresistive element 120. Note that, in the case of five-value conversion, four selection transistors are provided in parallel.

### (Example of Write Operation)

An example of a write operation to the memory cell 100 according to the present embodiment will be described with reference to FIG. 10.

In the initial state, all the transistors T1 to T9 illustrated in FIG. 10 are turned off. When data is written to the magnetoresistive element 120 of the memory cell 100, the selection transistor T1 and the fuse transistor T2 are turned on. Here, the high control signal FA(n) is supplied to the selection transistor T1, and the control signal of the low level FB(a) is supplied to the fuse transistor T2.

As a result, a current I1 flows from the potential line of the VFUSE to the magnetoresistive element 120 via the fuse transistor T2. Note that the VFUSE (1 to 4 V) is changed by the control circuit 5 according to information to be written (for example, 0, 1, 2, 3). For example, the first voltage, the second voltage, and the third voltage are generated as described above. In response thereto, for example, the first current I1a, the second current I1b, and the third current I1c (the first current I1a<the second current I1b<the third current I1c) are generated (see FIG. 11). When the first current I1a flows through the magnetoresistive element 120, the magnetoresistive element 120 changes from a resistance state of a certain resistance state (for example, “slightly short-circuited”) to the resistance state of “0”. When the second current I1b flows through the magnetoresistive element 120, the magnetoresistive element 120 changes from a certain resistance state to the resistance state of “1”. When the third current I1c flows through the magnetoresistive element 120, the magnetoresistive element 120 changes from a certain resistance state to the resistance state of “completely short-circuited”. As a result, data (0, 1, 2, 3) is written into the magnetoresistive element 120.

Thereafter, when the writing to the magnetoresistive element 120 is completed, all the transistors T1 to T9 illustrated in FIG. 10 are turned off and return to the initial state.

### (Example of Read Operation)

An example of a read operation to the memory cell 100 according to the present embodiment will be described with reference to FIG. 10.

To read data from the magnetoresistive element 120 of the memory cell 100, the selection transistor T1, the charge transistor T3, and the bit line selection transistor T4 are turned on. Here, the high control signal FA(n) is supplied to the selection transistor T1, the control signal FC(a) of the low level is supplied to the charge transistor T3, and the high control signal CL is supplied to the bit line selection transistor T4.

As a result, the magnetoresistive element 120 to be read is selected, and a read current 12 flows from the charge transistor T3 to the magnetoresistive element 120 via the bit line selection transistor T4. A path through which the read current 12 flows is a bias path of the magnetoresistive element 120. Here, the voltage Vm at the first connection point P1 is input to the first input terminal of the comparator 52 according to the read current I2.

Meanwhile, to generate the reference voltage Vref, the third to fifth reference transistors T5 to T7 of the reference voltage generator 51 are turned on. Here, the reference voltage generator 51 supplies the control signal RC of the low level, the control signal RCL of the high level, and the control signal RA1 of the high level to the respective gates of the third to fifth reference transistors T5 to T7.

As a result, the first reference resistance element R1 is biased by the power supply voltage VDD in the reference voltage generator 51, and the first reference current 13 is generated. Here, the reference voltage Vref at the second connection point P2 is input to the second input terminal of the comparator 52 according to the first reference current I3.

While the first reference current 13 flows through the first reference resistance element R1, the comparator 52 compares the voltage (Vm) at the first connection point P1 in the read circuit 50 with the reference voltage (Vref) at the second connection point P2 in the reference voltage generator 51, and reads the state of the magnetoresistive element 120 (first comparison operation).

In the first comparison operation, while the read current 12 flows through the magnetoresistive element 120, the potential (Vm) at the first connection point P1 is a potential corresponding to the resistance value of the magnetoresistive element 120. In the first comparison operation, while the current flows through the first reference resistance element R1, the potential (Vref) at the second connection point P2 becomes a potential corresponding to the resistance value of the first reference resistance element R1 (for example, 500 (Ω). Therefore, the first comparison operation of comparing a voltage signal SA1 (Vm) with a reference voltage signal SA2 (Vref) in the comparator 52 is substantially equivalent to an operation of comparing the resistance value of the magnetoresistive element 120 with the resistance value of the first reference resistance element R1 (that is, a first threshold value).

The comparator 52 determines whether the voltage Vm at the first connection point P1 is equal to or lower than the reference voltage Vref at the second connection point P2 (Vm≤Vref). When it is determined that the voltage Vm is equal to or lower than the reference voltage Vref, the comparator 52 outputs a signal (comparison result) corresponding to the information “0”. On the other hand, when it is determined that the voltage Vm is larger than the reference voltage Vref, the comparator 52 outputs a signal (comparison result) corresponding to the information “1”. The information is stored by the first register of the read circuit 50. Thereafter, the read circuit 50 executes a second comparison operation.

While the second reference current 14 flows through the second reference resistance element R2, the comparator 52 compares the voltage (Vm) at the first connection point P1 in the read circuit 50 with the reference voltage (Vref) at the second connection point P2 in the reference voltage generator 51, and reads the state of the magnetoresistive element 120 (second comparison operation). The second comparison operation is similar to the first comparison operation except that the reference voltage Vref serving as a threshold value is different from that in the first comparison operation. The reference voltage Vref is a potential corresponding to the resistance value of the second reference resistance element R2 (for example, 2,000 (Ω)). After the second comparison operation is executed, the information “0” or “1” is stored in the second register of the read circuit 50. Thereafter, the read circuit 50 executes a third comparison operation.

While the third reference current 15 flows through the third reference resistance element R3, the comparator 52 compares the voltage (Vm) at the first connection point P1 in the read circuit 50 with the reference voltage (Vref) at the second connection point P2 in the reference voltage generator 51, and reads the state of the magnetoresistive element 120 (third comparison operation). The second comparison operation is similar to the first comparison operation except that the reference voltage Vref serving as a threshold value is different from that in the first comparison operation. The reference voltage Vref is a potential corresponding to the resistance value of the third reference resistance element R3 (for example, 8,000 (Ω)). After the third comparison operation is executed, the information “0” or “1” is stored in the third register of the read circuit 50. Thereafter, the read circuit 50 ends the comparison operation.

Thereafter, the read circuit 50 realizes four-value conversion (0, 1, 2, 3) based on each comparison result, that is, each determination result input into the first register to the fourth register (see FIG. 8). For example, when each of the determination results of the first register, the second register, and the third register is 0, the information becomes 0, and when the determination result of the first register is 1 and each of the determination results of the second register and the third register is 0, the information becomes 1. Further, when each of the determination results of the first register and the second register is 1 and the determination result of the third register is 0, the information becomes 2, and when each of the determination results of the first register, the second register, and the third register is 1, the information becomes 3.

Note that the method of reading information from the magnetoresistive element 120 is not limited to the above-described example. As a method of reading information from the magnetoresistive element 120, any method can be used as long as the resistance state of the magnetoresistive element 120 can be identified using three threshold values. For example, in the above description, the first comparison operation is performed first, then the second comparison operation is performed, and finally the third comparison operation is performed, but the order of the comparison operations may be reversely performed.

In the above description, the comparison operation is performed three times, but whether to perform the next comparison operation may be switched according to the comparison result. That is, the operation may proceed to the second comparison operation only when it is determined that the voltage Vm is larger than the reference voltage Vref in the first comparison operation, and the operation may proceed to the third comparison operation only when it is determined that the voltage Vm is larger than the reference voltage Vref in the second comparison operation. Here, the comparator 52 outputs a signal (comparison result) corresponding to the information “0” when it is determined that the voltage Vm is equal to or lower than the reference voltage Vref in the first comparison operation, and outputs a signal (comparison result) corresponding to the information “1” when it is determined that the voltage Vm is equal to or lower than the reference voltage Vref in the second comparison operation. In addition, the comparator 52 outputs a signal (comparison result) corresponding to information “2” when it is determined that the voltage Vm is equal to or lower than the reference voltage Vref in the third comparison operation, and outputs a signal (comparison result) corresponding to the information “3” when it is determined that the voltage Vm is higher than the reference voltage Vref in the third comparison operation.

In the above description, the comparison operation is performed three times to realize four-value conversion, but when realizing five-value conversion, necessary circuits such as a fourth reference resistance element may be added, and the comparison operation similar to the above description may be performed four times.

### 1-8. Action and Effect

As described above, according to the present embodiment, the storage device 1 includes the magnetoresistive element (magnetoresistive storage element) 120 that changes to at least four identifiable resistance states, and the write unit (for example, the write circuit 60) that changes the magnetoresistive element 120 to at least four identifiable resistance states by changing the magnetization direction of the magnetoresistive element 120 or causing a blow current to flow through the magnetoresistive element 120. As a result, since the magnetoresistive element 120 can be changed to at least four resistance states, at least four-value conversion is realized, and memory capacity can be increased without increasing the number of memory cells 100 or the like. Therefore, memory capacity can be increased in a space-saving manner.

Furthermore, the magnetoresistive element 120 may include the magnetization fixed layer 122, the storage layer 124, the insulating layer (for example, the tunnel barrier layer 123) provided between the magnetization fixed layer 122 and the storage layer 124, and the conductive layer 126 connecting the magnetization fixed layer 122 to the storage layer 124. As a result, the magnetoresistive element 120 can be reliably changed to at least four identifiable resistance states.

In addition, the write unit may cause a blow current to flow through the magnetoresistive element 120 to destroy the conductive layer 126 and bring the conductive layer 126 into a non-conductive state. Thus, the resistance state of the magnetoresistive element 120 can be changed.

In addition, the write unit may cause a blow current to flow through the magnetoresistive element 120 to destroy the insulating layer and bring the insulating layer into a conductive state. Thus, the resistance state of the magnetoresistive element 120 can be changed.

Furthermore, the magnetoresistive element 120 may further include the connection layer (for example, the contact layer 103 or the contact layer 104) laminated on the magnetization fixed layer 122 or the storage layer 124, and the write unit may cause a blow current to flow through the magnetoresistive element 120 to destroy the connection layer and bring the connection layer into a non-conductive state. Thus, the resistance state of the magnetoresistive element 120 can be changed.

In addition, the four resistance states may include a resistance state in which the conductive layer 126 is destroyed and is in a non-conductive state. As a result, at least four identifiable resistance states can be realized.

The four resistance states may include a resistance state in which the insulating layer is destroyed and is in a conductive state. As a result, at least four identifiable resistance states can be realized.

Furthermore, the magnetoresistive element 120 may further include the connection layer (for example, the contact layer 103 or the contact layer 104) laminated on the magnetization fixed layer 122 or the storage layer 124, and the four resistance states may include a resistance state in which the connection layer is destroyed and is in a non-conductive state. As a result, at least four identifiable resistance states can be realized.

In addition, the four resistance states may include a resistance state in which the magnetization direction of the magnetization fixed layer 122 and the magnetization direction of the storage layer 124 are parallel to each other, and a resistance state in which the magnetization direction of the magnetization fixed layer 122 and the magnetization direction of the storage layer 124 are antiparallel to each other. As a result, at least four identifiable resistance states can be realized.

In addition, the conductive layer 126 may be formed on the outer peripheral surface of the magnetoresistive element 120 to cross the insulating layer. Thus, the conductive layer 126 can be easily formed in the magnetoresistive element 120.

In addition, the conductive layer 126 may be a degenerated layer of one or both of the magnetization fixed layer 122 and the storage layer 124. As a result, the conductive layer 126 can be easily formed in the magnetoresistive element 120 using the degenerated layer.

In addition, when realizing four-value conversion, the write unit may change the magnitude of the blow current to change the magnetoresistive element 120 to at least two identifiable resistance states. Accordingly, it is possible to reliably change the resistance state of the magnetoresistive element 120.

Furthermore, the magnetoresistive element 120 may be an element that changes to five identifiable resistance states, and the write unit may change the magnetoresistive element 120 to five identifiable resistance states by changing the magnetization direction of the magnetoresistive element 120 or causing a blow current to flow through the magnetoresistive element 120. As a result, since five-value conversion is realized, memory capacity can be increased without increasing the number of memory cells 100 and the like.

In addition, when realizing five-value conversion, the write unit may change the magnitude of the blow current to change the magnetoresistive element 120 to three identifiable resistance states. Accordingly, it is possible to reliably change the resistance state of the magnetoresistive element 120.

The write unit may change the magnitude of the blow current using a plurality of power supply voltages having different output voltages (for example, the power supply voltage VFUSE (1 to 4 V)). As a result, blow currents having different magnitudes can be easily generated.

In addition, the write unit may include a plurality of transistors connected in parallel (for example, each of the selection transistors T1a, T1b, and T1c), and the magnitude of the blow current may be changed by changing conduction and non-conduction of each of the plurality of transistors. As a result, blow currents having different magnitudes can be easily generated.

Furthermore, the storage device 1 may further include a read unit (for example, the read circuit 50) that reads a voltage related to the resistance value of the magnetoresistive element 120, and the read unit may include a generation unit (for example, the reference voltage generator 51) that generates a plurality of reference voltages for determining at least four identifiable resistance states and a determination unit (for example, the comparator 52) that compares a voltage and the plurality of reference voltages and determines at least four identifiable resistance states. As a result, at least four identifiable resistance states of the magnetoresistive element 120 can be reliably determined.

The magnetoresistive element 120 may be an element that changes to five identifiable resistance states, the generation unit may generate a plurality of reference voltages for determining the five identifiable resistance states, and the determination unit may compare a voltage and the plurality of reference voltages and determine the five identifiable resistance states. Accordingly, it is possible to reliably determine the five identifiable resistance states of the magnetoresistive element 120.

### 2. Other Embodiments

The processing according to the above-described embodiments (or modifications) may be performed in various different modes (modifications) other than the above-described embodiments. For example, among the various types of processing described in the above embodiments, all or a part of the processing described as being automatically performed can be manually performed, or all or a part of the processing described as being manually performed can be automatically performed by a known method. In addition, information including processing procedure, specific name, and various types of data and parameters illustrated in the document and the drawings can be freely and selectively changed unless otherwise specified. For example, the various types of information illustrated in each drawing are not limited to the illustrated information.

In addition, each component of each device illustrated in the drawings is functionally conceptual, and is not necessarily physically configured as illustrated in the drawings. That is, a specific form of distribution and integration of each device is not limited to the illustrated form, and all or a part thereof can be functionally or physically distributed and integrated in any unit according to various loads, usage conditions, and the like.

In addition, the above-described embodiments (or modifications) can be appropriately combined within a range that does not contradict processing contents. Furthermore, the effects described in the present specification are merely examples and are not limited, and other effects may be obtained.

### 3. Configuration Example of Electronic Apparatus

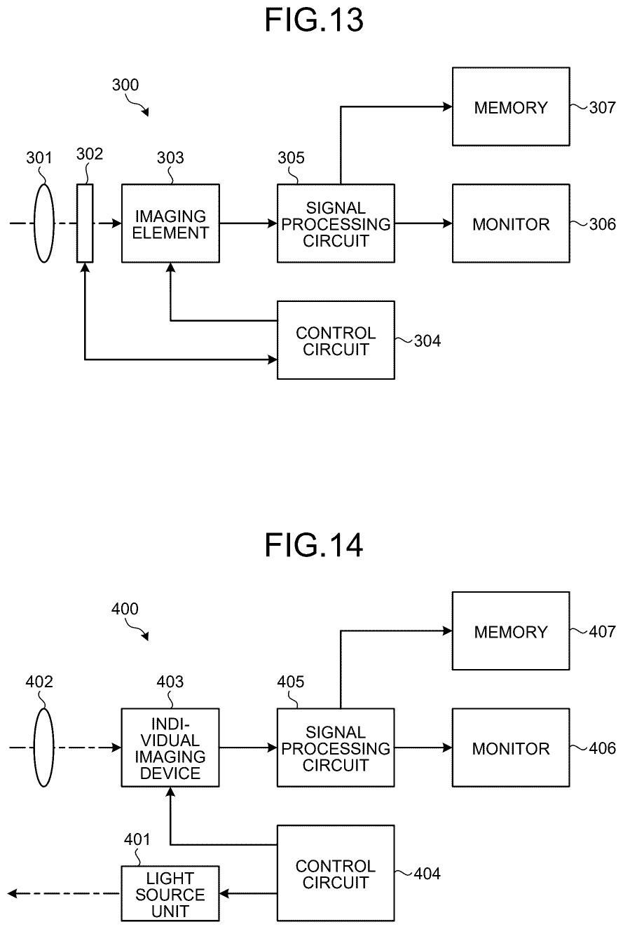

As an electronic apparatus to which the storage device 1 according to the above embodiment (including modifications) is applied, an imaging device 300, a distance measurement device 400, and a game apparatus 900 will be described with reference to FIGS. 13 to 16. For example, each of the imaging device 300, the distance measurement device 400, and the game apparatus 900 uses the storage device 1 according to each of the above embodiments as a memory.

### 3-1. Imaging device

The imaging device 300 to which the storage device 1 according to the above embodiment is applied will be described with reference to FIG. 13. FIG. 13 is a diagram illustrating an example of a schematic configuration of the imaging device 300. The imaging device 300 is an example of the electronic apparatus to which the storage device 1 according to the present embodiment is applied. Examples of the imaging device 300 include electronic devices such as a digital still camera, a video camera, a smartphone having an imaging function, a mobile phone, and the like.

As illustrated in FIG. 13, the imaging device 300 includes an optical system 301, a shutter device 302, an imaging element 303, a control circuit (drive circuit) 304, a signal processing circuit 305, a monitor 306, and a memory 307. The imaging device 300 can capture a still image and a moving image.

The optical system 301 includes one or a plurality of lenses. The optical system 301 guides light (incident light) from a subject to the imaging element 303 and forms an image on a light receiving surface of the imaging element 303.

The shutter device 302 is disposed between the optical system 301 and the imaging element 303. The shutter device 302 controls a light irradiation period and a light shielding period with respect to the imaging element 303 according to the control of the control circuit 304.

The imaging element 303 accumulates signal charges for a certain period according to light formed on the light receiving surface via the optical system 301 and the shutter device 302. The signal charges accumulated in the imaging element 303 is transferred in accordance with a drive signal (timing signal) supplied from the control circuit 304.

The control circuit 304 outputs the drive signal for controlling a transfer operation of the imaging element 303 and a shutter operation of the shutter device 302 to drive the imaging element 303 and the shutter device 302.

The signal processing circuit 305 performs various types of signal processing on the signal charges output from the imaging element 303. An image (image data) obtained by performing the signal processing by the signal processing circuit 305 is supplied to the monitor 306 and also supplied to the memory 307.

The monitor 306 displays a moving image or a still image captured by the imaging element 303 based on the image data supplied from the signal processing circuit 305. As the monitor 306, for example, a panel type display device such as a liquid crystal panel or an organic electro luminescence (EL) panel is used.

The memory 307 stores the image data supplied from the signal processing circuit 305, that is, image data of the moving image or the still image captured by the imaging element 303. The memory 307 corresponds to the storage device 1 according to the above embodiment.

Also in the imaging device 300 configured in this manner, low-power-consumption writing can be implemented by using the above-described storage device 1 as the memory 307.

### 3-2. Distance Measurement Device

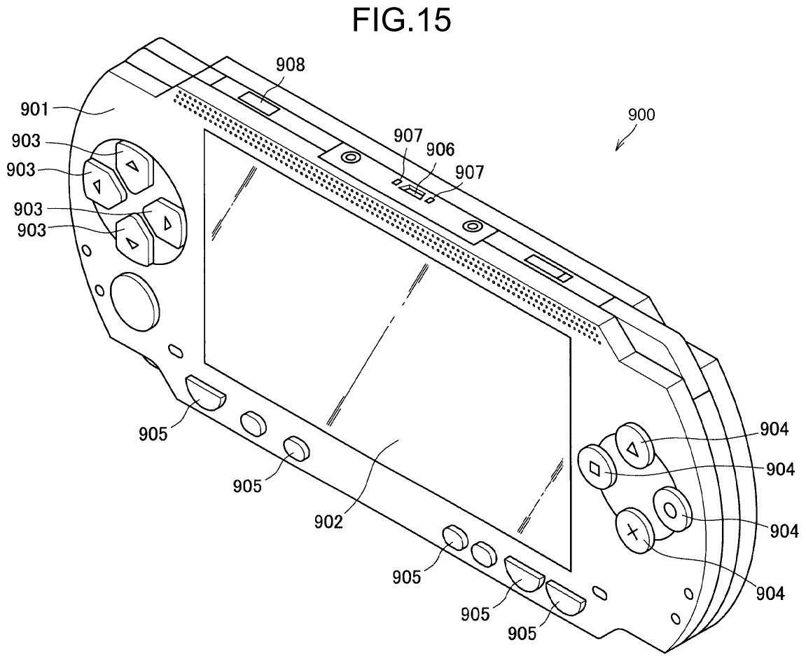

The distance measurement device 400 to which the storage device 1 according to the above embodiment is applied will be described with reference to FIG. 14. FIG. 14 is a diagram illustrating an example of a schematic configuration of the distance measurement device 400. The distance measurement device 400 is an example of the electronic apparatus to which the storage device 1 according to the present embodiment is applied.

As illustrated in FIG. 14, the distance measurement device (distance image sensor) 400 includes a light source unit 401, an optical system 402, a solid-state imaging device (imaging element) 403, a control circuit (drive circuit) 404, a signal processing circuit 405, a monitor 406, and a memory 407. The distance measurement device 400 can acquire a distance image according to a distance to a subject by projecting light from the light source unit 401 toward the subject and receiving light (modulated light or pulsed light) reflected from a surface of the subject.

The light source unit 401 projects light toward the subject. As the light source unit 401, for example, a vertical cavity surface emitting laser (VCSEL) array that emits laser light as a surface light source or a laser diode array in which laser diodes are arrayed on a line is used. Note that the laser diode array is supported by a predetermined drive unit (not illustrated), and is scanned in a direction perpendicular to the array direction of the laser diodes.

The optical system 402 includes one or a plurality of lenses. The optical system 402 guides light (incident light) from the subject to the solid-state imaging device 403 to form an image on a light receiving surface (sensor unit) of the solid-state imaging device 403.

The solid-state imaging device 403 stores signal charges according to the light of the image formed on the light receiving surface via the optical system 402. A distance signal indicating the distance obtained from a light reception signal (APD OUT) output from the solid-state imaging device 403 is supplied to the signal processing circuit 405. As the solid-state imaging device 403, for example, a solid-state imaging element such as an image sensor is used.

The control circuit 404 outputs a drive signal (control signal) for controlling operations of the light source unit 401, the solid-state imaging device 403, and the like to drive the light source unit 401, the solid-state imaging device 403, and the like.

The signal processing circuit 405 performs various types of signal processing on the distance signal supplied from the solid-state imaging device 403. For example, the signal processing circuit 405 performs image processing (for example, histogram processing, peak detection processing, and the like) of constructing the distance image on the basis of the distance signal. An image (image data) obtained by performing the signal processing by the signal processing circuit 405 is supplied to the monitor 406 and also supplied to the memory 407.

The monitor 406 displays the distance image captured by the imaging element 303 on the basis of the image data supplied from the signal processing circuit 405. As the monitor 406, for example, a panel type display device such as a liquid crystal panel or an organic EL panel is used.

The memory 407 stores the image data supplied from the signal processing circuit 405, that is, the image data of the distance image captured by the imaging element 303. The memory 407 corresponds to the storage device 1 according to the above embodiment.

Also in the distance measurement device 400 configured in this manner, low-power-consumption writing can be implemented by using the above-described storage device 1 as the memory 407.

### 3-3. Game Device

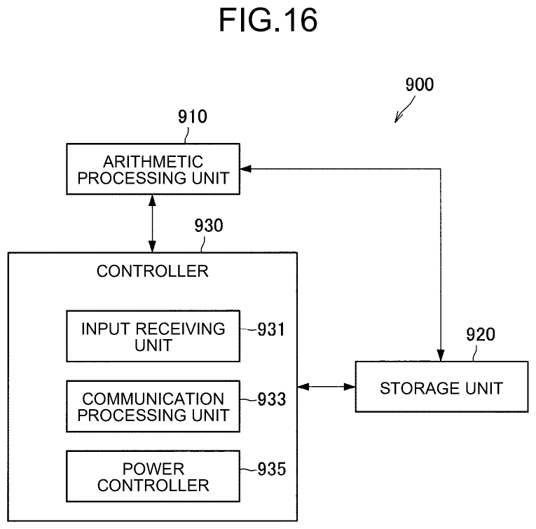

The game device 900 to which the storage device 1 according to the above embodiment is applied will be described with reference to FIGS. 15 and 16. FIG. 15 is a perspective view (external perspective view) illustrating an example of the schematic configuration of the game device 900. FIG. 16 is a block diagram illustrating an example of the schematic configuration of the game device 900. The game device 900 is an example of the electronic apparatus to which the storage device 1 according to the present embodiment is applied.

As illustrated in FIG. 15, for example, the game device 900 has an appearance in which each component is disposed inside and outside an outer casing 901 formed in a horizontally long flat shape.

On the front surface of the outer casing 901, a display panel 902 is provided at the center thereof in the longitudinal direction. Further, operation keys 903 and operation keys 904 are provided on the left and right sides of the display panel 902, respectively, spaced apart from each other in the circumferential direction. An operation key 905 is provided at a lower end of the front surface of the outer casing 901. The operation keys 903, 904, and 905 function as direction keys, determination keys, or the like, and are used for selection of menu items displayed on the display panel 902, progress of a game, or the like.

On the upper surface of the outer casing 901, a connection terminal 906 for connecting an external device, a power supply terminal 907, a light receiving window 908 for performing infrared communication with the external device, and the like are provided.

As illustrated in FIG. 16, the game device 900 includes an arithmetic processing unit 910 including a central processing unit (CPU), a storage unit 920 that stores various types of information, and a controller 930 that controls each configuration of the game device 900. Power is supplied to the arithmetic processing unit 910 and the controller 930 from, for example, a battery (not illustrated) or the like.

The arithmetic processing unit 910 generates a menu screen for allowing a user to set various types of information or select an application. In addition, the arithmetic processing unit 910 executes the application selected by the user.

The storage unit 920 stores various types of information set by the user. The storage unit 920 corresponds to the storage device 1 according to the above embodiment.

The controller 930 includes an input receiving unit 931, a communication processing unit 933, and a power controller 935. The input receiving unit 931 detects, for example, the states of the operation keys 903, 904, and 905. Furthermore, the communication processing unit 933 performs communication processing with an external device. The power controller 935 controls power supplied to each unit of the game device 900.

Also in the game device 900 configured in this manner, low-power-consumption writing can be implemented by using the above-described storage device 1 as the storage unit 920.

It is noted that the storage device 1 according to each of the above-described embodiments may be mounted on the same semiconductor chip together with a semiconductor circuit forming an arithmetic device or the like to form a semiconductor device (System-on-a-Chip: SoC).

Furthermore, the storage device 1 according to the above embodiment can be mounted on various electronic devices on which a memory (storage unit) can be mounted as described above. For example, the storage device 1 may be mounted on various electronic devices such as a hard disk drive (HDD), a notebook personal computer (PC), a mobile device (for example, a smartphone, a tablet PC, or the like), a personal digital assistant (PDA), a wearable device, and a music device in addition to the imaging device 300 and the game device 900. For example, the storage device 1 is used as various memories such as a storage.

### 4. Appendix

Note that the present technology can also have the following configurations.
(1)

A storage device comprising:
a magnetoresistive storage element that can be changed to at least four identifiable resistance states; and
a write unit that changes the magnetoresistive storage element into the at least four identifiable resistance states by changing a magnetization direction of the magnetoresistive storage element or causing a blow current to flow through the magnetoresistive storage element.
(2)

The storage device according to (1), wherein
the magnetoresistive storage element includes a magnetization fixed layer, a storage layer, an insulating layer provided between the magnetization fixed layer and the storage layer, and a conductive layer connecting the magnetization fixed layer to the storage layer.
(3)

The storage device according to (2), wherein
the write unit causes the blow current to flow through the magnetoresistive storage element to destroy the conductive layer and bring the conductive layer into a non-conductive state.
(4)

The storage device according to (2) or (3), wherein
the write unit causes the blow current to flow through the magnetoresistive storage element to destroy the insulating layer and bring the insulating layer into a conductive state.
(5)

The storage device according to any one of (2) to (4), wherein
the magnetoresistive storage element further includes a connection layer laminated on the magnetization fixed layer or the storage layer, and
the write unit causes the blow current to flow through the magnetoresistive storage element to destroy the connection layer and bring the connection layer into a non-conductive state.
(6)

The storage device according to any one of (2) to (5), wherein
the four resistance states include a resistance state in which the conductive layer is destroyed and is in a non-conductive state.
(7)

The storage device according to any one of (2) to (6), wherein
the four resistance states include a resistance state in which the insulating layer is destroyed and is in a conductive state.
(8)

The storage device according to any one of (2) to (7), wherein
the magnetoresistive storage element further includes a connection layer laminated on the magnetization fixed layer or the storage layer, and
the four resistance states include a resistance state in which the connection layer is destroyed and is in a non-conductive state.
(9)

The storage device according to any one of (6) to (8), wherein
the four resistance states include a resistance state in which the magnetization direction of the magnetization fixed layer and the magnetization direction of the storage layer are parallel to each other, and a resistance state in which the magnetization direction of the magnetization fixed layer and the magnetization direction of the storage layer are antiparallel to each other.
(10)

The storage device according to any one of (2) to (9), wherein
the conductive layer is formed on an outer peripheral surface of the magnetoresistive storage element to cross the insulating layer.
(11)

The storage device according to any one of (2) to (10), wherein
the conductive layer is a degenerated layer of one or both of the magnetization fixed layer and the storage layer.
(12)

The storage device according to any one of (1) to (11), wherein
the write unit changes a magnitude of the blow current to change the magnetoresistive storage element into at least two identifiable resistance states.
(13)

The storage device according to any one of (1) to (12), wherein
the magnetoresistive storage element is an element that can be changed to five identifiable resistance states, and
the write unit changes the magnetoresistive storage element into the five identifiable resistance states by changing the magnetization direction of the magnetoresistive storage element or causing the blow current to flow through the magnetoresistive storage element.
(14)

The storage device according to (13), wherein
the write unit changes a magnitude of the blow current to change the magnetoresistive storage element into three identifiable resistance states.
(15)

The storage device according to any one of (1) to (14), wherein
the write unit changes a magnitude of the blow current using a plurality of power supply voltages having different output voltages.
(16)

The storage device according to any one of (1) to (14), wherein
the write unit includes a plurality of transistors connected in parallel and changes conduction and non-conduction of each of the plurality of transistors to change a magnitude of the blow current.
(17)

The storage device according to any one of (1) to (16), further comprising:
a read unit that reads a voltage related to a resistance value of the magnetoresistive storage element, wherein
the read unit includes
a generation unit that generates a plurality of reference voltages to determine the at least four identifiable resistance states, and
a determination unit that compares the voltage with the plurality of reference voltages and determines the at least four identifiable resistance states.
(18)

The storage device according to (17), wherein
the magnetoresistive storage element is an element that changes to five identifiable resistance states,
the generation unit generates a plurality of reference voltages to determine the five identifiable resistance states, and
the determination unit compares the voltage with the plurality of reference voltages and determines the five identifiable resistance states.
(19)

An electronic apparatus comprising:
a storage device that stores information, wherein
the storage device includes
a magnetoresistive storage element that changes to at least four identifiable resistance states, and
a write unit that changes the magnetoresistive storage element into the at least four identifiable resistance states by changing a magnetization direction of the magnetoresistive storage element or causing a blow current to flow through the magnetoresistive storage element.
(20)

A storage device control method comprising:
changing a resistance state of a magnetoresistive storage element to at least four identifiable resistance states by changing a magnetization direction of the magnetoresistive storage element or causing a blow current to flow through the magnetoresistive storage element, the magnetoresistive storage element being variable between the at least four identifiable resistance states.
(21)

An electronic apparatus including the storage device according to any one of (1) to (18).
(22)

A storage device control method of controlling the storage device according to any one of (1) to (18).

### REFERENCE SIGNS LIST

1 STORAGE DEVICE
5 CONTROL CIRCUIT
6 VOLTAGE GENERATION CIRCUIT
10 MEMORY CELL ARRAY
11 WORD LINE
12 BIT LINE
13 SOURCE LINE
20 WORD LINE CONTROL CIRCUIT
30 BIT LINE CONTROL CIRCUIT
40 SENSE AMPLIFIER
50 READ CIRCUIT
51 REFERENCE VOLTAGE GENERATOR
52 COMPARATOR
60 WRITE CIRCUIT
100 MEMORY CELL
101 WIRING
102 WIRING
103 CONTACT LAYER
104 CONTACT LAYER
110 SELECTION ELEMENT
120 MAGNETORESISTIVE ELEMENT (MAGNETORESISTIVE STORAGE ELEMENT)
121 BASE LAYER
122 MAGNETIZATION FIXED LAYER
123 TUNNEL BARRIER LAYER
124 STORAGE LAYER
125 CAP LAYER
126 CONDUCTIVE LAYER
300 IMAGING DEVICE
305 SIGNAL PROCESSING CIRCUIT
307 MEMORY
400 DISTANCE MEASUREMENT DEVICE
405 SIGNAL PROCESSING CIRCUIT
407 MEMORY
900 GAME DEVICE
910 ARITHMETIC PROCESSING UNIT
920 STORAGE UNIT
R1 REFERENCE RESISTANCE ELEMENT
R2 REFERENCE RESISTANCE ELEMENT
R3 REFERENCE RESISTANCE ELEMENT
T1 SELECTION TRANSISTOR
T2 FUSE TRANSISTOR
T3 CHARGE TRANSISTOR
T4 BIT LINE SELECTION TRANSISTOR
T5 REFERENCE TRANSISTOR
T6 REFERENCE TRANSISTOR
T7 REFERENCE TRANSISTOR
T8 REFERENCE TRANSISTOR
T9 REFERENCE TRANSISTOR

1. A storage device comprising:
a magnetoresistive storage element that can be changed to at least four identifiable resistance states; and
a write unit that changes the magnetoresistive storage element into the at least four identifiable resistance states by changing a magnetization direction of the magnetoresistive storage element or causing a blow current to flow through the magnetoresistive storage element.

2. The storage device according to claim 1, wherein
the magnetoresistive storage element includes a magnetization fixed layer, a storage layer, an insulating layer provided between the magnetization fixed layer and the storage layer, and a conductive layer connecting the magnetization fixed layer to the storage layer.

3. The storage device according to claim 2, wherein
the write unit causes the blow current to flow through the magnetoresistive storage element to destroy the conductive layer and bring the conductive layer into a non-conductive state.

4. The storage device according to claim 2, wherein
the write unit causes the blow current to flow through the magnetoresistive storage element to destroy the insulating layer and bring the insulating layer into a conductive state.

5. The storage device according to claim 2, wherein
the magnetoresistive storage element further includes a connection layer laminated on the magnetization fixed layer or the storage layer, and
the write unit causes the blow current to flow through the magnetoresistive storage element to destroy the connection layer and bring the connection layer into a non-conductive state.

6. The storage device according to claim 2, wherein
the four resistance states include a resistance state in which the conductive layer is destroyed and is in a non-conductive state.

7. The storage device according to claim 2, wherein
the four resistance states include a resistance state in which the insulating layer is destroyed and is in a conductive state.

8. The storage device according to claim 2, wherein
the magnetoresistive storage element further includes a connection layer laminated on the magnetization fixed layer or the storage layer, and
the four resistance states include a resistance state in which the connection layer is destroyed and is in a non-conductive state.

9. The storage device according to claim 6, wherein
the four resistance states include a resistance state in which the magnetization direction of the magnetization fixed layer and the magnetization direction of the storage layer are parallel to each other, and a resistance state in which the magnetization direction of the magnetization fixed layer and the magnetization direction of the storage layer are antiparallel to each other.

10. The storage device according to claim 2, wherein
the conductive layer is formed on an outer peripheral surface of the magnetoresistive storage element to cross the insulating layer.

11. The storage device according to claim 2, wherein
the conductive layer is a degenerated layer of one or both of the magnetization fixed layer and the storage layer.

12. The storage device according to claim 1, wherein
the write unit changes a magnitude of the blow current to change the magnetoresistive storage element into at least two identifiable resistance states.

13. The storage device according to claim 1, wherein
the magnetoresistive storage element is an element that can be changed to five identifiable resistance states, and
the write unit changes the magnetoresistive storage element into the five identifiable resistance states by changing the magnetization direction of the magnetoresistive storage element or causing the blow current to flow through the magnetoresistive storage element.

14. The storage device according to claim 13, wherein
the write unit changes a magnitude of the blow current to change the magnetoresistive storage element into three identifiable resistance states.

15. The storage device according to claim 1, wherein
the write unit changes a magnitude of the blow current using a plurality of power supply voltages having different output voltages.

16. The storage device according to claim 1, wherein
the write unit includes a plurality of transistors connected in parallel and changes conduction and non-conduction of each of the plurality of transistors to change a magnitude of the blow current.

17. The storage device according to claim 1, further comprising:
a read unit that reads a voltage related to a resistance value of the magnetoresistive storage element, wherein
the read unit includes
a generation unit that generates a plurality of reference voltages to determine the at least four identifiable resistance states, and
a determination unit that compares the voltage with the plurality of reference voltages and determines the at least four identifiable resistance states.

18. The storage device according to claim 17, wherein
the magnetoresistive storage element is an element that changes to five identifiable resistance states,
the generation unit generates a plurality of reference voltages to determine the five identifiable resistance states, and
the determination unit compares the voltage with the plurality of reference voltages and determines the five identifiable resistance states.

19. An electronic apparatus comprising:
a storage device that stores information, wherein
the storage device includes
a magnetoresistive storage element that changes to at least four identifiable resistance states, and
a write unit that changes the magnetoresistive storage element into the at least four identifiable resistance states by changing a magnetization direction of the magnetoresistive storage element or causing a blow current to flow through the magnetoresistive storage element.

20. A storage device control method comprising:
changing a resistance state of a magnetoresistive storage element to at least four identifiable resistance states by changing a magnetization direction of the magnetoresistive storage element or causing a blow current to flow through the magnetoresistive storage element, the magnetoresistive storage element being variable between the at least four identifiable resistance states.
